(19) United States
(12) Patent Application Publication
(10) Pub. No.: US 2005/0147844 A1
(43) Pub. Date: Jul. 7, 2005

(54) White oled devices with color filter arrays

(75) Inventors: Tukaram K. Hatwar, Penfield, NY (US); Jeffrey P. Spindler, Rochester, NY (US); Christopher T. Brown, Rochester, NY (US); Michele L. Ricks, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/751,352

(22) Filed: Jan. 5, 2004

(51) Int. Cl. H05B 33/14

(52) U.S. Cl. 428/690; 428/917; 313/504; 313/506; 313/112; 257/98

(57) ABSTRACT

An OLED device produces white light more effectively matching the response of multicolor filters in an OLED device including an anode and a cathode and an organic EL element disposed between the anode and cathode having at least two different dopants for collectively emitting white light. The device includes a color filter array disposed over the EL element and including at least three separate filters having bandpass spectra for passing red, green, and blue light, respectively, in response to white light to produce preselected color outputs, and the composition of one or more of the dopants being selected to change the spectrum of the white light to be compatible with the spectrum of the color filters by having peak responses in the white light spectrum corresponding to the bandpass spectra of the red and blue color filters whereby the white light more effectively matches the responses of the color filters.

### FIELD OF THE INVENTION

The present invention relates to white OLED devices with color filter arrays.

### BACKGROUND OF THE INVENTION

An organic light-emitting diode device, also called an OLED device, commonly includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing and capability for full color flat emission displays. Tang et al. described this multilayer OLED device in their U.S. Pat. Nos. 4,769,292 and 4,885,211.

A white-emitting electroluminescent (EL) layer can be used to form a multicolor device. Each pixel is coupled with a color filter element as part of a color filter array (CFA) to achieve a pixilated multicolor display. The organic EL layer is common to all pixels and the final color as perceived by the viewer is dictated by that pixel's corresponding color filter element. Therefore a multicolor or RGB device can be produced without requiring any patterning of the organic EL layers. An example of a white CFA top-emitting device is shown in U.S. Pat. No. 6,392,340.

White light producing OLED devices should be bright, efficient, and generally have Commission International d'Eclairage (CIE) chromaticity coordinates of about (0.33, 0.33). In any event, in accordance with this disclosure, white light is that light which is perceived by a user as having a white color. The following patents and publications disclose the preparation of organic OLED devices capable of producing white light, comprising a hole-transporting layer, and an organic luminescent layer, and interposed between a pair of electrodes.

White light producing OLED devices have been reported before by J. Shi (U.S. Pat. No. 5,683,823) wherein the luminescent layer includes red and blue light-emitting materials uniformly dispersed in a host emitting material. Sato et al. in JP 07-142169 discloses an OLED device, capable of emitting white light, made by forming a blue light-emitting layer next to the hole-transporting layer, and followed by a green light-emitting layer having a region containing a red fluorescent layer.

Kido et al., in Science, Vol. 267, p. 1332 (1995) and in APL Vol. 64, p. 815 (1994), report a white light-producing OLED device. In this device, three emitter layers with different carrier transport properties, each emitting blue, green, or red light, are used to generate white light. Littman et al. in U.S. Pat. No. 5,405,709 disclose another white emitting device, which is capable of emitting white light in response to hole-electron recombination, and comprises a fluorescent in a visible light range from bluish green to red. Recently, Deshpande et al., in Applied Physics Letters, Vol. 75, p. 888 (1999), published a white OLED device using red, blue, and green luminescent layers separated by a hole-blocking layer.

The filters generally used for the color filter arrays are commercially available. However, existing white emitters have not always matched the response of existing color filters. In particular, it is sometimes necessary to increase the current density to one or more of the individual colors of pixels, thus leading to shortened lifetime of that color and to undesirable color shifts in emission with aging of the device.

A problem in the application of white OLED devices, when used with color filters, is that the intensity of one or more of the red, green, and blue components of the emission spectrum is frequently lower than desired. Therefore, passing the white light from the OLED through the red, green, and blue color filters provides light with a lower efficiency than desired. Consequently, the power that is required to produce a white color in the display by mixing red, green, and blue light can also be higher than desired.

### SUMMARY OF THE INVENTION

It is therefore an object of the present invention to provide a white-emitting OLED device that more effectively matches the responses of color filters in a color filter array.

This object is achieved by an OLED device for producing white light which more effectively matches the response of multicolor filters in an OLED device, comprising:
a) an anode and a spaced cathode;
b) an organic EL element disposed between the anode and cathode having at least two different dopants for collectively emitting white light;
c) a color filter array disposed over the EL element and including at least three separate filters having bandpass spectra for passing red, green, and blue light, respectively, in response to white light to produce preselected color outputs; and
d) the composition of one or more of the dopants being selected to change the spectrum of the white light to be compatible with the spectrum of the color filters by having peak responses in the white light spectrum corresponding to the bandpass spectra of the red and blue color filters so that the color filters more effectively match the response of the white light.

### Advantages

It is an advantage of this invention that it provides improved efficiency of the individual color emissions, in particular the red emission, thereby providing lower power consumption by the overall OLED device. It is a further advantage of this invention that by providing a more balanced current density for each color, it helps reduce color shifts of the device with aging. It is a further advantage of this invention that it provides an improved color gamut.

### BRIEF DESCRIPTION OF THE DRAWINGS

FIG. 1 is a cross-sectional view of an OLED device according to a first embodiment of this invention;

FIG. 2 is a cross-sectional view of an OLED device according to another embodiment of this invention;

FIG. 3 is a graphical representation of the emission spectrum of a prior art white OLED device in comparison to commonly used color filters;

FIG. 4 is a graphical representation in CIE color space of the color gamut of the above prior art white OLED device;

FIG. 5 is a graphical representation of the emission spectrum of one embodiment of a white OLED device in accordance with this invention in comparison to commonly used color filters; and

FIG. 6 is a graphical representation in CIE color space of the color gamut of the above inventive white OLED device.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “pixel” is employed in its art-recognized usage to designate an area of a display panel that can be stimulated to emit light independently of other areas. The term “OLED device” or “organic light-emitting display” is used in its art-recognized meaning of a display device comprising organic light-emitting diodes as pixels. A color OLED device emits light of at least one color. The term “multicolor” is employed to describe a display panel that is capable of emitting light of a different hue in different areas. In particular, it is employed to describe a display panel that is capable of displaying images of different colors. These areas are not necessarily contiguous. The term “full color” is employed to describe multicolor display panels that are capable of emitting in the red, green, and blue regions of the visible spectrum and displaying images in any combination of hues. The red, green, and blue colors constitute the three primary colors from which all other colors can be generated by appropriate mixing. The term “hue” refers to the intensity profile of light emission within the visible spectrum, with different hues exhibiting visually discernible differences in color. The pixel or subpixel is generally used to designate the smallest addressable unit in a display panel. For a monochrome display, there is no distinction between pixel or subpixel. The term “subpixel” is used in multicolor display panels and is employed to designate any portion of a pixel which can be independently addressable to emit a specific color. For example, a blue subpixel is that portion of a pixel which can be addressed to emit blue light. In a full color display, a pixel generally comprises three primary-color subpixels, namely blue, green, and red. The term “pitch” is used to designate the distance separating two pixels or subpixels in a display panel. Thus, a subpixel pitch means the separation between two subpixels.

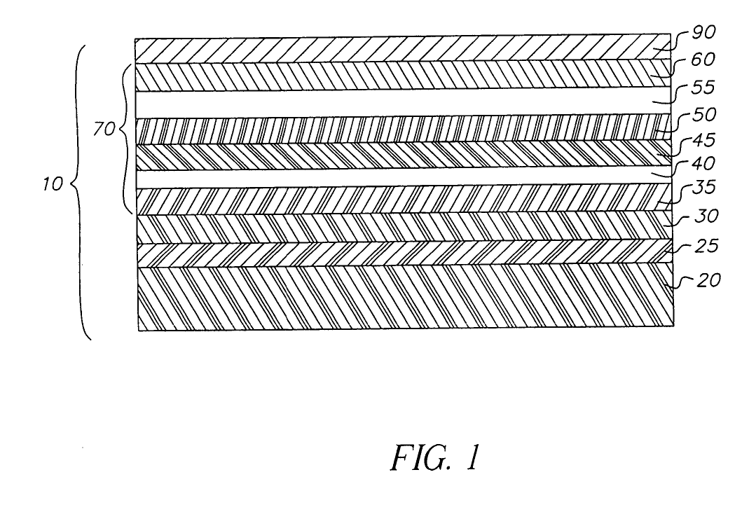

Turning now to FIG. 1, there is shown a cross-sectional view of a pixel of a light-emitting OLED device 10 that can be used according to a first embodiment of the present invention. The OLED device 10 includes at a minimum a substrate 20, an anode 30, a cathode 90 spaced from anode 30, and a light-emitting layer 50. The OLED device can also include color filter 25, a hole-injecting layer 35, a hole-transporting layer 40, a second hole-transporting layer 45 that can also be a light-emitting layer, an electron-transporting layer 55, and an electron-injecting layer 60. Hole-injecting layer 35, hole-transporting layer 40, light-emitting layer 50, electron-transporting layer 55, and electron-injecting layer 60 comprise organic EL element 70 that is disposed between anode 30 and cathode 90 and that, for the purposes of this invention, includes at least two different dopants for collectively emitting white light. These components will be described in more detail.

Substrate 20 can be an organic solid, an inorganic solid, or a combination of organic and inorganic solids. Substrate 20 can be rigid or flexible and can be processed as separate individual pieces, such as sheets or wafers, or as a continuous roll. Typical substrate materials include glass, plastic, metal, ceramic, semiconductor, metal oxide, semiconductor oxide, semiconductor nitride, or combinations thereof. Substrate 20 can be a homogeneous mixture of materials, a composite of materials, or multiple layers of materials. Substrate 20 can be an OLED substrate, that is a substrate commonly used for preparing OLED devices, e.g. active-matrix low-temperature polysilicon or amorphous-silicon TFT substrate. The substrate 20 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials, or any others commonly used in the formation of OLED devices, which can be either passive-matrix devices or active-matrix devices.

The color filter 25 includes color filter elements for the color to be emitted from the pixel or subpixel of OLED device 10 and is part of a color filter array that is disposed over organic EL element 70. Color filter 25 is constructed to pass a preselected color of light in response to white light, so as to produce a preselected color output. An array of three different kinds of color filters 25 that pass red, green, and blue light, respectively, is particularly useful in a full color OLED device. Several types of color filters are known in the art. One type of color filter 25 is formed on a second transparent substrate and then aligned with the pixels of the first substrate 20. An alternative type of color filter 25 is formed directly over the elements of OLED device 10. In a display comprising multiple pixels, the space between the individual color filter elements can also be filled with a black matrix (not shown) to reduce pixel cross talk and improve the display's contrast. While color filter 25 is shown here as being located between anode 30 and substrate 20, it can alternatively be located on the outside surface of substrate 20. For a top-emitting device, color filter 25 can be located over cathode 90.

An electrode is formed over substrate 20 and is most commonly configured as an anode 30. When EL emission is viewed through the substrate 20, anode 30 should be transparent or substantially transparent to the emission of interest. Common transparent anode materials useful in this invention are indium-tin oxide and tin oxide, but other metal oxides can work including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material. For applications where EL emission is viewed through the top electrode, the transmissive characteristics of the anode material are immaterial and any conductive material can be used, transparent, opaque or reflective. Example conductors for this application include, but are not limited to, gold, iridium, molybdenum, palladium, and platinum. The preferred anode materials, transmissive or otherwise, have a work function of 4.1 eV or greater. Desired anode materials can be deposited by any suitable way such as evaporation, sputtering, chemical vapor deposition, or electrochemical means. Anode materials can be patterned using well known photolithographic processes.

While not always necessary, it is often useful that a hole-injecting layer 35 be formed over anode 30 in an organic light-emitting display. The hole-injecting material can serve to improve the film formation property of subsequent organic layers and to facilitate injection of holes into the hole-transporting layer. Suitable materials for use in hole-injecting layer 35 include, but are not limited to, porphyrinic compounds as described in U.S. Pat. No. 4,720,432, plasma-deposited fluorocarbon polymers as described in U.S. Pat. No. 6,208,075, and inorganic oxides including vanadium oxide (VOx), molybdenum oxide (MoOx), nickel oxide (NiOx), etc. Alternative hole-injecting materials reportedly useful in organic EL devices are described in EP 0 891 121 A1 and EP 1 029 909 A1.

While not always necessary, it is often useful that a hole-transporting layer 40 be formed and disposed over anode 30. Desired hole-transporting materials can be deposited by any suitable way such as evaporation, sputtering, chemical vapor deposition, electrochemical means, thermal transfer, or laser thermal transfer from a donor material. Hole-transporting materials useful in hole-transporting layer 40 are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and/or comprising at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A 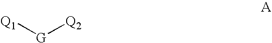
wherein:
Q₁ and Q₂ are independently selected aromatic tertiary amine moieties; and
G is a linking group such as an arylene, cycloalkylene, or alkylene group of a carbon to carbon bond.

In one embodiment, at least one of Q₁ and Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula 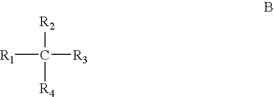
where:
R₁ and R₂ each independently represent a hydrogen atom, an aryl group, or an alkyl group or R₁ and R₂ together represent the atoms completing a cycloalkyl group; and
R₃ and R₄ each independently represent an aryl group, which is in turn substituted with a diaryl substituted amino group, as indicated by structural Formula C 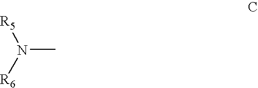
   wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D 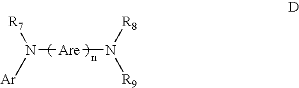
wherein:
each Are is an independently selected arylene group, such as a phenylene or anthracene moiety;
n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms—e.g., cyclopentyl, cyclohexyl, and cycloheptyl ring structures. The aryl and arylene moieties are usually phenyl and phenylene moieties.

The hole-transporting layer in an OLED device can be formed of a single or a mixture of aromatic tertiary amine compounds. Specifically, one can employ a triarylamine, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron-injecting and transporting layer. Illustrative of useful aromatic tertiary amines are the following:
1,1-Bis(4-di-p-tolylaminophenyl)cyclohexane;
1,1-Bis(4-di-p-tolylaminophenyl)-4-phenylcyclohexane;
4,4′-Bis(diphenylamino)quadriphenyl;
Bis(4-dimethylamino-2-methylphenyl)-phenylmethane;
N,N,N-Tri(p-tolyl)amine;
4-(di-p-tolylamino)-4′-[4-(di-p-tolylamino)-styryl]stilbene;
N,N,N′,N′-Tetra-p-tolyl-4-4′-diaminobiphenyl;
N,N,N′,N′-Tetraphenyl-4,4′-diaminobiphenyl;
N-Phenylcarbazole;
Poly(N-vinylcarbazole);
N,N′-di-1-naphthalenyl-N,N′-diphenyl-4,4′-diaminobiphenyl;
4,4′-Bis[N-(1-naphthyl)-N-phenylamino]biphenyl;
4,4″-Bis[N-(1-naphthyl)-N-phenylamino]p-terphenyl;
4,4′-Bis[N-(2-naphthyl)-N-phenylamino]biphenyl;
4,4′-Bis[N-(3-acenaphthenyl)-N-phenylamino]biphenyl;
1,5-Bis[N-(1-naphthyl)-N-phenylamino]naphthalene;
4,4′-Bis[N-(9-anthryl)-N-phenylamino]biphenyl;
4,4″-Bis[N-(1-anthryl)-N-phenylamino]-p-terphenyl;
4,4′-Bis[N-(2-phenanthryl)-N-phenylamino]biphenyl;
4,4′-Bis[N-(8-fluoranthenyl)-N-phenylamino]biphenyl;
4,4′-Bis[N-(2-pyrenyl)-N-phenylamino]biphenyl;
4,4′-Bis[N-(2-naphthacenyl)-N-phenylamino]biphenyl;
4,4′-Bis[N-(2-perylenyl)-N-phenylamino]biphenyl;
4,4′-Bis[N-(1-coronenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N′-Tetra(2-naphthyl)-4,4″-diamino-p-terphenyl;
4,4′-Bis {N-phenyl-N-[4-(1-naphthyl)-phenyl]amino}biphenyl;
4,4′-Bis[N-phenyl-N-(2-pyrenyl)amino]biphenyl;
2,6-Bis[N,N-di(2-naphthyl)amine]fluorene; and
1,5-Bis[N-(1-naphthyl)-N-phenylamino]naphthalene.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-emitting layer 50 produces light in response to hole-electron recombination. Light-emitting layer 50 is commonly disposed over hole-transporting layer 40. Desired organic light-emitting materials can be deposited by any suitable way such as evaporation, sputtering, chemical vapor deposition, electrochemical means, or radiation thermal transfer from a donor material. Useful organic light-emitting materials are well known. As more fully described in U.S. Pat. Nos. 4,769,292 and 5,935,721, the light-emitting layers of the organic EL element comprise a luminescent or fluorescent material where electroluminescence is produced as a result of electron-hole pair recombination in this region. The light-emitting layers can be comprised of a single material, but more commonly include a host material doped with a guest compound or dopant where light emission comes primarily from the dopant. The dopant is selected to produce color light having a particular spectrum. The host materials in the light-emitting layers can be an electron-transporting material, as defined below, a hole-transporting material, as defined above, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material.

An important relationship for choosing a dye as a dopant is a comparison of the bandgap potential which is defined as the energy difference between the highest occupied molecular orbital and the lowest unoccupied molecular orbital of the molecule. For efficient energy transfer from the host material to the dopant molecule, a necessary condition is that the band gap of the dopant is smaller than that of the host material.

Host and emitting molecules known to be of use include, but are not limited to, those disclosed in U.S. Pat. Nos. 4,768,292; 5,141,671; 5,150,006; 5,151,629; 5,294,870; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red. 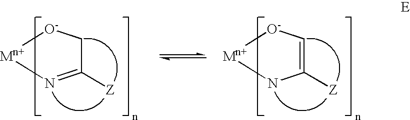
wherein:
M represents a metal;
n is an integer of from 1 to 3; and
Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)].

The host material in light-emitting layer 50 can be an anthracene derivative having hydrocarbon or substituted hydrocarbon substituents at the 9 and 10 positions. For example, derivatives of 9,10-di-(2-naphthyl)anthracene (Formula F) constitute one class of useful host materials capable of supporting electroluminescence, and are particularly suitable for light emission of wavelengths longer than 400 nm, e.g., blue, green, yellow, orange or red. 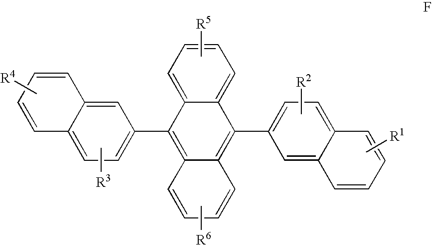
wherein R¹, R², R³, R⁴, R⁵, and R⁶ represent one or more substituents on each ring where each substituent is individually selected from the following groups:
Group 1: hydrogen, or alkyl of from 1 to 24 carbon atoms;
Group 2: aryl or substituted aryl of from 5 to 20 carbon atoms;
Group 3: carbon atoms from 4 to 24 necessary to complete a fused aromatic ring of anthracenyl, pyrenyl, or perylenyl;
Group 4: heteroaryl or substituted heteroaryl of from 5 to 24 carbon atoms as necessary to complete a fused heteroaromatic ring of furyl, thienyl, pyridyl, quinolinyl or other heterocyclic systems;
Group 5: alkoxylamino, alkylamino, or arylamino of from 1 to 24 carbon atoms; and
Group 6: fluorine, chlorine, bromine or cyano.

Benzazole derivatives (Formula G) constitute another class of useful host materials capable of supporting electroluminescence, and are particularly suitable for light emission of wavelengths longer than 400 nm, e.g., blue, green, yellow, orange or red. 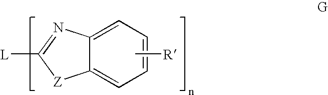
where:
n is an integer of 3 to 8;
Z is O, NR or S;
R′is hydrogen; alkyl of from 1 to 24 carbon atoms, for example, propyl, t-butyl, heptyl, and the like; aryl or heteroatom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and
L is a linkage unit including alkyl, aryl, substituted alkyl, or substituted aryl, which conjugately or unconjugately connects the multiple benzazoles together.

An example of a useful benzazole is 2,2′, 2″-(1,3,5-phenylene)tris[1-phenyl-1H-benzimidazole].

Desirable fluorescent dopants include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds. Illustrative examples of useful dopants include, but are not limited to, the following:

| | |
|---|---|
| | L1 |
| 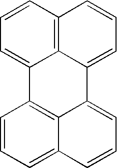 | |
| | L2 |
| 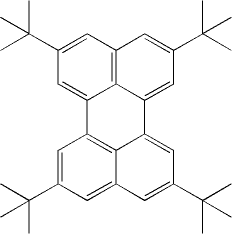 | |
| | L3 |
| 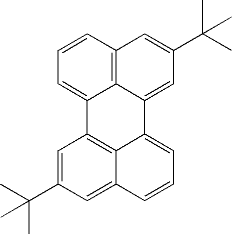 | |
| | L4 |
| 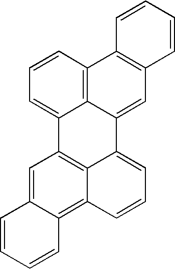 | |
| | L5 |
| 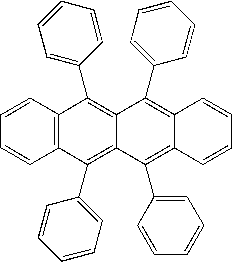 | |
| | L6 |
| 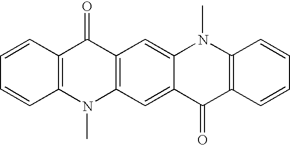 | |
| | L7 |
| 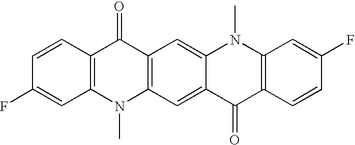 | |
| | L8 |
| 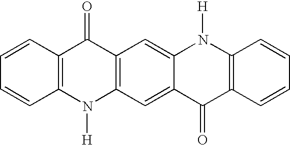 | |

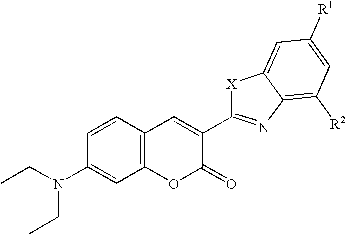

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

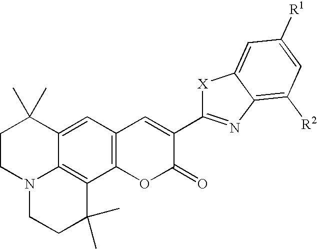

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

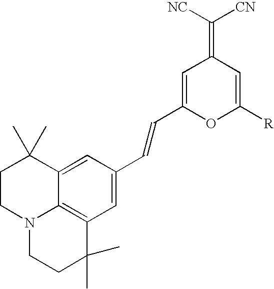

| | R |
|---|---|
| L37 | phenyl |
| L38 | methyl |
| L39 | t-butyl |
| L40 | mesityl |

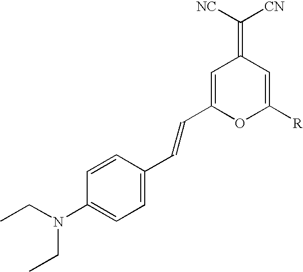

| | R |
|---|---|
| L41 | phenyl |
| L42 | methyl |
| L43 | t-butyl |
| L44 | mesityl |

| | |
|---|---|
| | L45 |
| 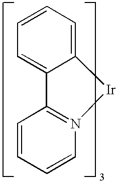 | |
| | L46 |
| 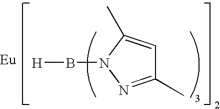 | |
| | L47 |
| 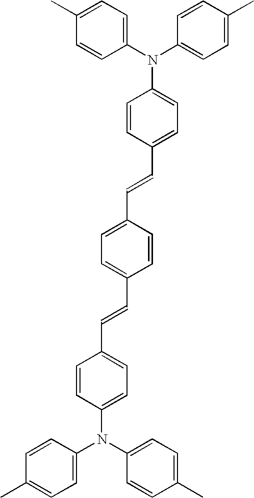 | |
| | L48 |
| 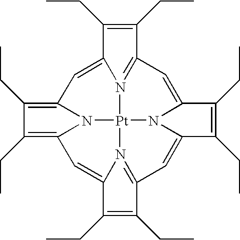 | |

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 B1 and references cited therein.

Certain blue, yellow, and red emissive materials can be particularly useful for this invention. The light-emitting blue dopant can include perylene or derivatives thereof, blue-emitting derivatives of distyrylbenzene or a distyrylbiphenyl, or a compound of the structure M1: 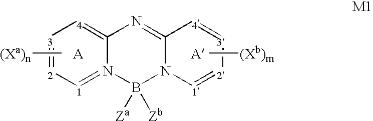
wherein:

A and A′ represent independent azine ring systems corresponding to 6-membered aromatic ring systems containing at least one nitrogen;
(X^{a})ₙ and (X^{b})ₘ represent one or more independently selected substituents and include acyclic substituents or are joined to form a ring fused to A or A′;
m and n are independently 0 to 4;
Z^{a} and Z^{b} are independently selected substituents;
1, 2, 3, 4, 1′, 2′, 3′, and 4′ are independently selected as either carbon or nitrogen atoms; and
wherein X^{a}, X^{b}, Z^{a}, and Z^{b}, 1, 2, 3, 4, 1′, 2′, 3′, and 4′ are selected to provide blue luminescence.

Some examples of the above class of dopants include the following:

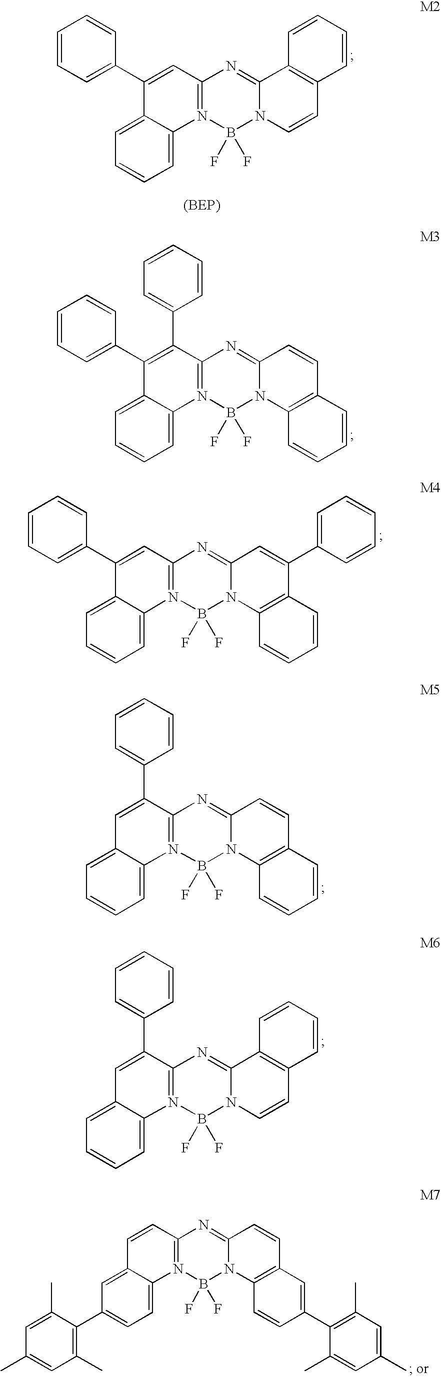

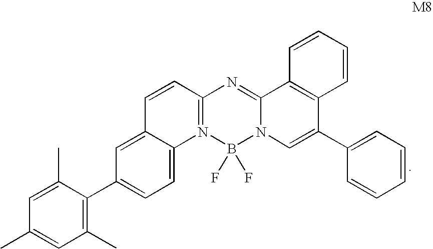

Another particularly useful class of blue dopants includes blue-emitting derivatives of such distyrylarenes as distyrylbenzene and distyrylbiphenyl, including compounds described in U.S. Pat. No. 5,121,029. Among derivatives of distyrylarenes that provide blue luminescence, particularly useful are those substituted with diarylamino groups, also known as distyrylamines. Examples include bis[2-[4-[N,N-diarylamino]phenyl]vinyl]-benzenes of the general structure N1 shown below: 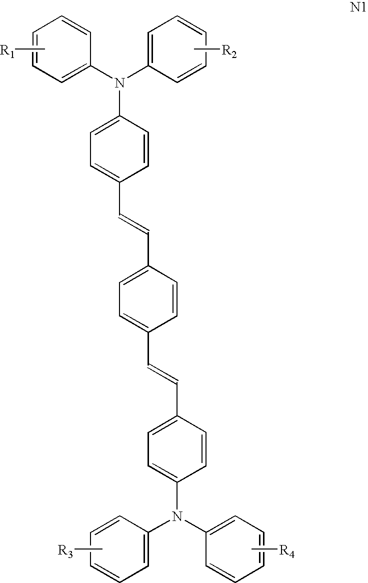
and bis[2-[4-[N,N-diarylamino]phenyl]vinyl]biphenyls of the general structure N2 shown below:

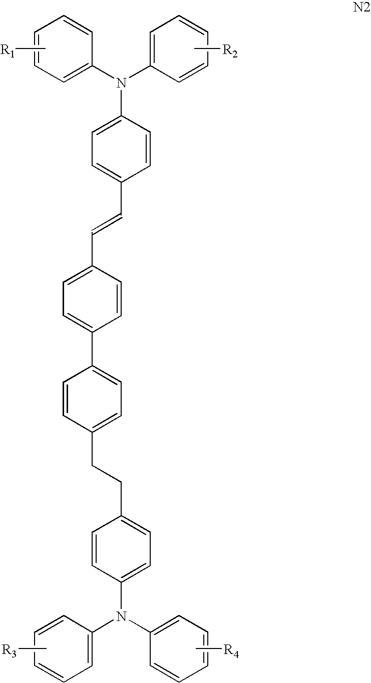

In Formulas N1 and N2, R₁-R₄ can be the same or different, and individually represent one or more substituents such as alkyl, aryl, fused aryl, halo, or cyano. In a preferred embodiment, R₁-R₄ are individually alkyl groups, each containing from one to about ten carbon atoms. A particularly preferred blue dopant of this class is 1,4-bis[2-[4-[N,N-di(p-tolyl)amino]phenyl]vinyl]benzene (BDTAPVB, Formula L47 above).

The light-emitting yellow dopant can include a compound of the following structures: 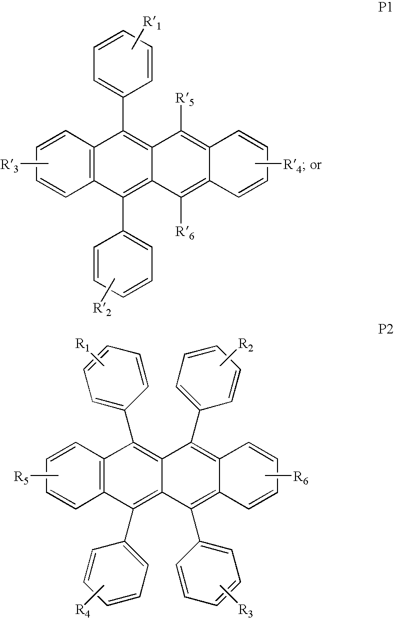
wherein R₁-R₆ represent one or more substituents on each ring and where each substituent is individually selected from one of the following:
Category 1: hydrogen, or alkyl of from 1 to 24 carbon atoms;
Category 2: aryl or substituted aryl of from 5 to 20 carbon atoms;
Category 3: hydrocarbon containing 4 to 24 carbon atoms, completing a fused aromatic ring or ring system;
Category 4: heteroaryl or substituted heteroaryl of from 5 to 24 carbon atoms such as thiazolyl, furyl, thienyl, pyridyl, quinolinyl or other heterocyclic systems, which are bonded via a single bond, or complete a fused heteroaromatic ring system;
Category 5: alkoxylamino, alkylamino, or arylamino of from 1 to 24 carbon atoms; or
Category 6: fluoro, chloro, bromo or cyano.

Examples of particularly useful yellow dopants include 5,6,11,12-tetraphenylnaphthacene (rubrene); 6,11-diphenyl-5,12-bis(4-(6-methyl-benzothiazol-2-yl)phenyl)naphthacene (DBzR) and 5,6,11,12-tetra(2-naphthyl)naphthacene (NR), the formulas of which are shown below:

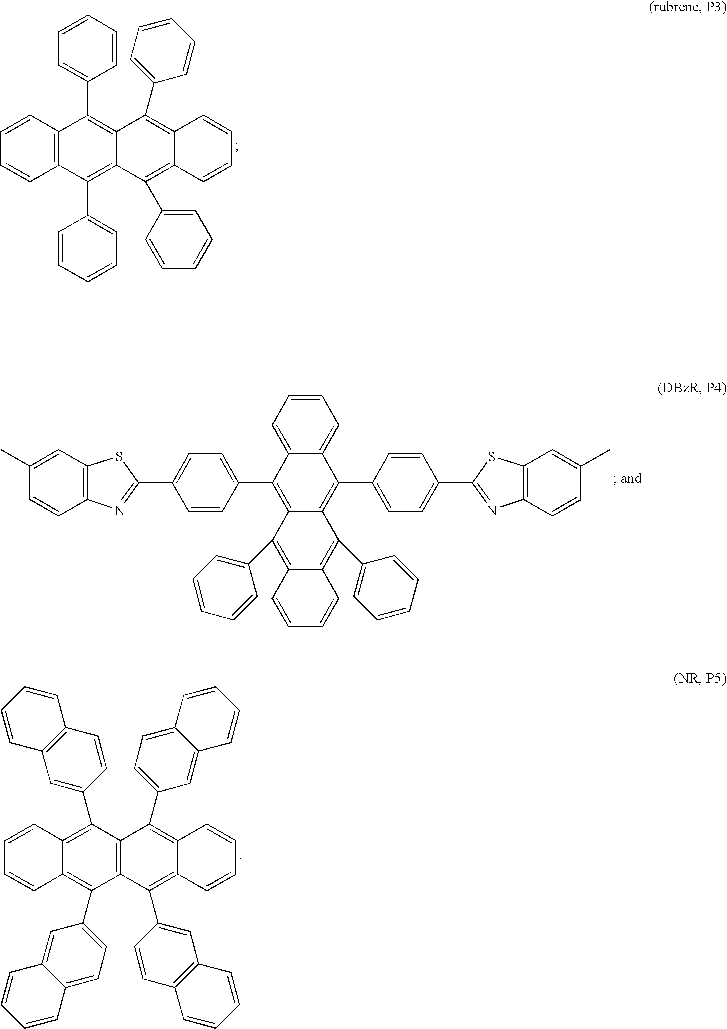

The yellow dopant can also be a mixture of compounds that would also be yellow dopants individually.

The light-emitting red dopant can include a diindenoperylene compound of the following structure Q1: 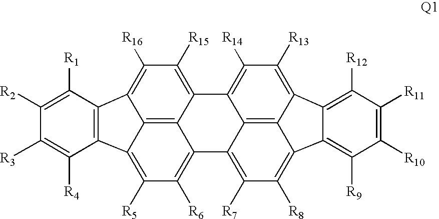
wherein:

R₁-R₁₆ are independently selected as hydro or substituents that provide red luminescence.

Illustrative examples of useful red dopants of this class include the following:

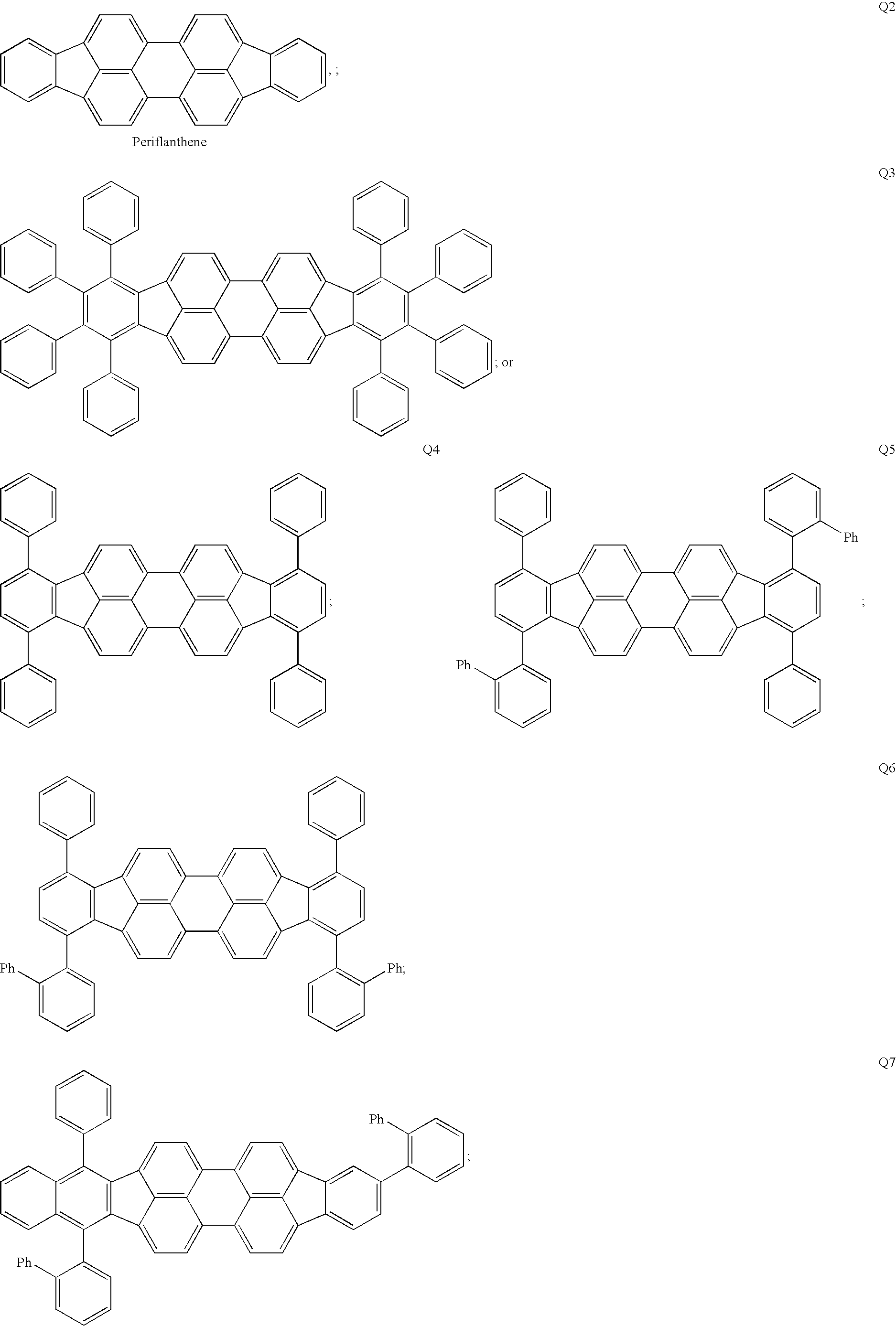

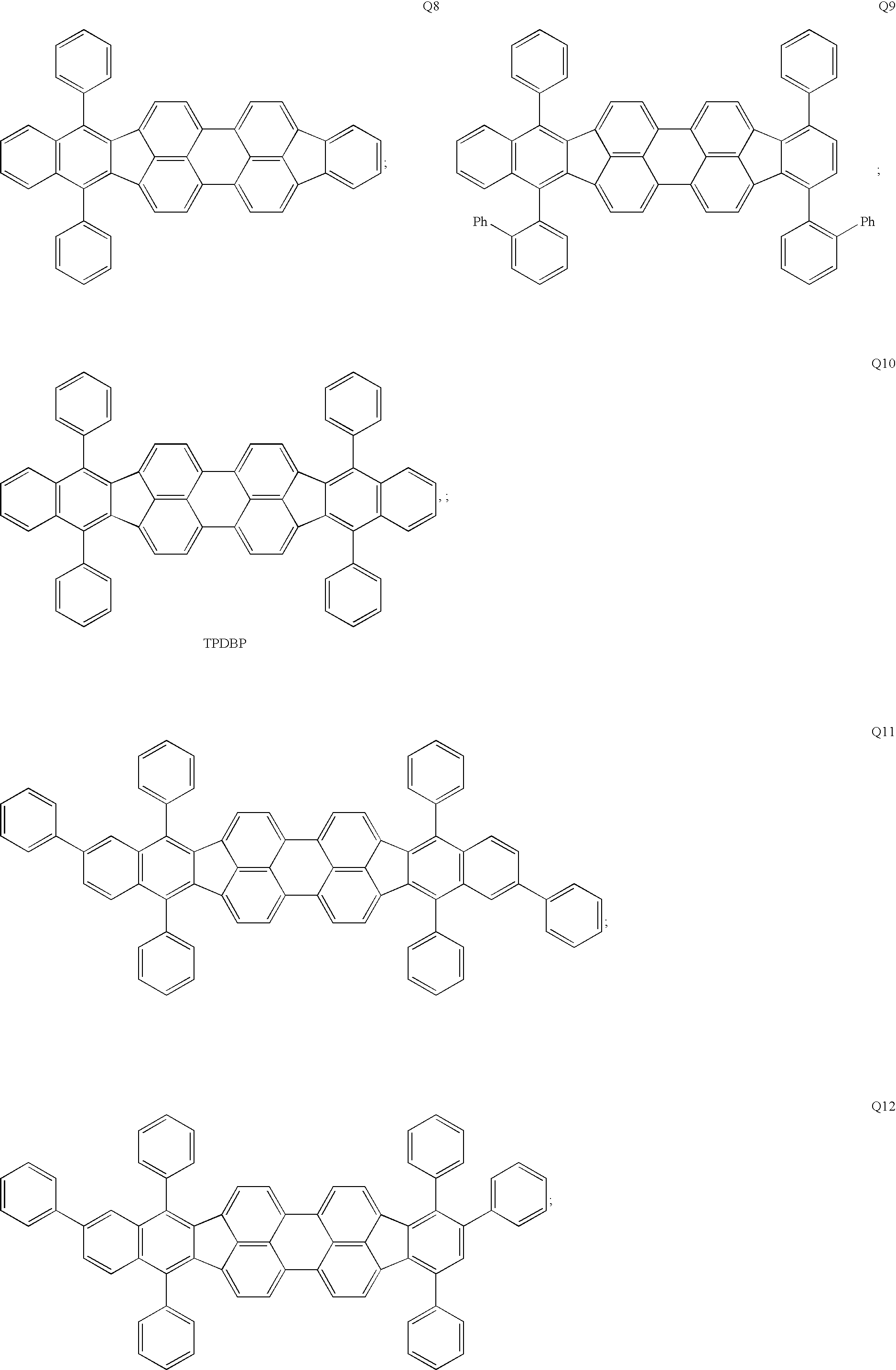

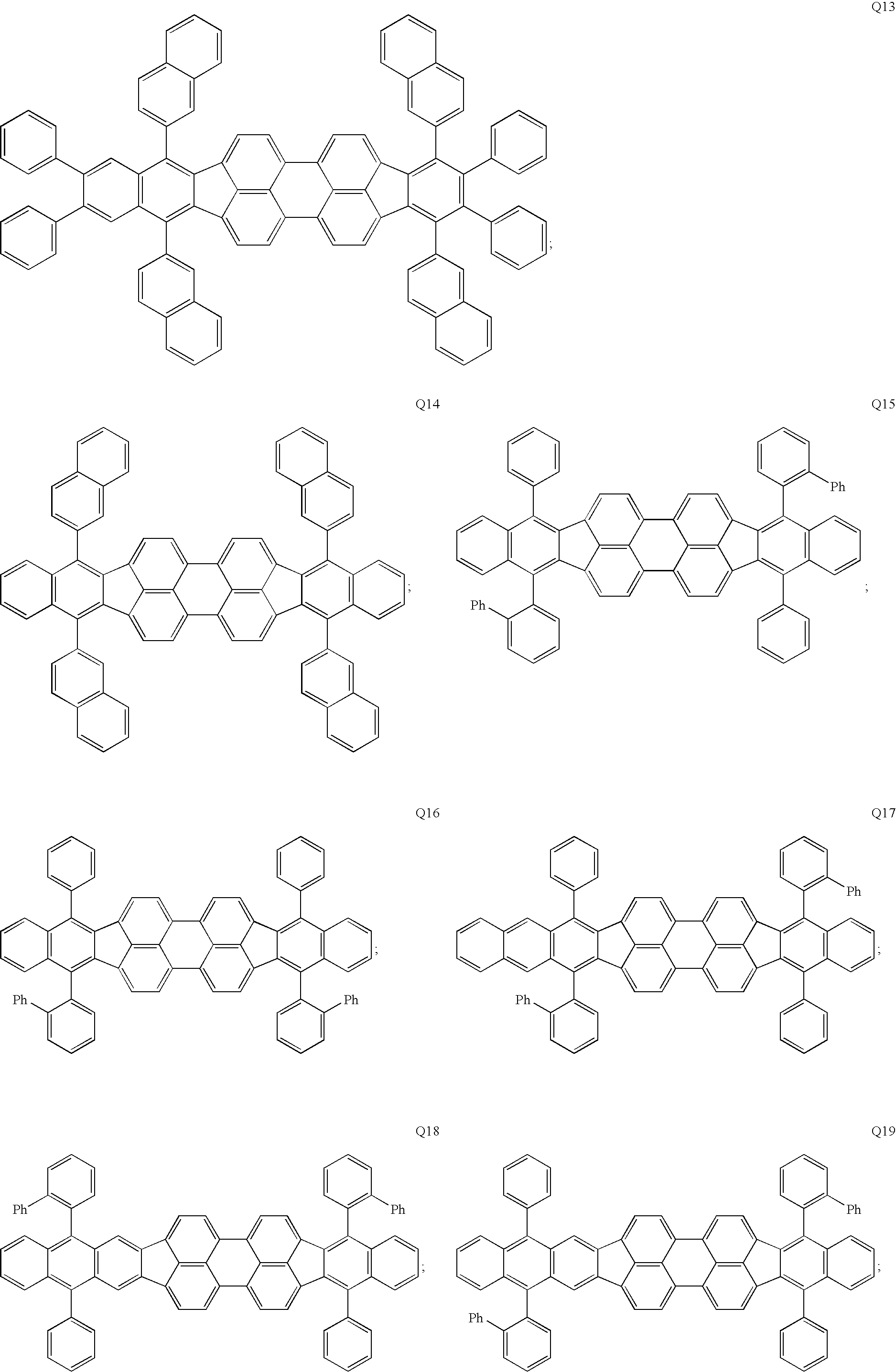

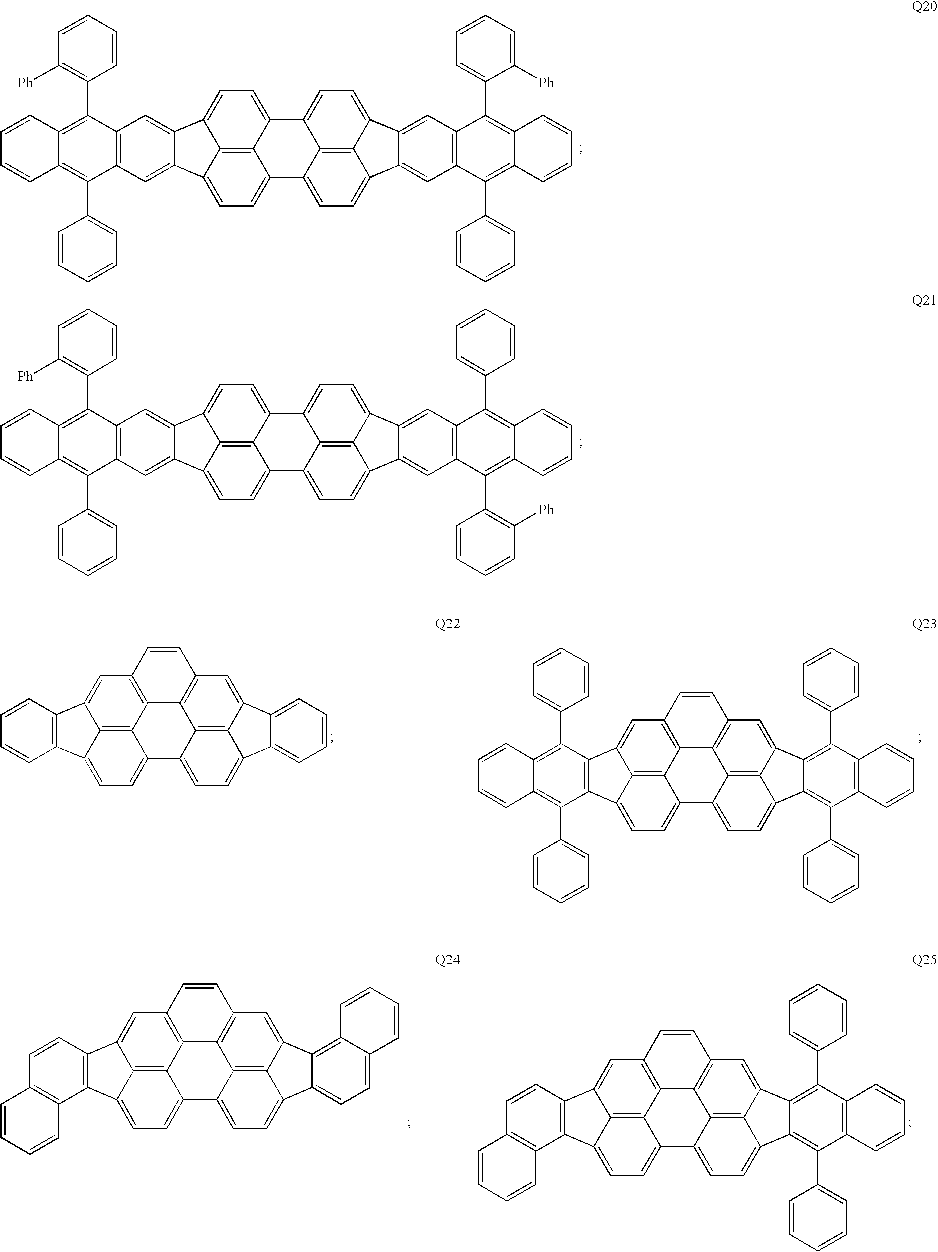

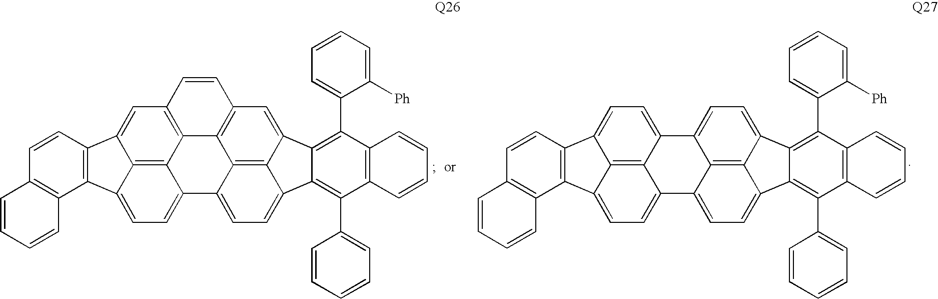

A particularly preferred diindenoperylene dopant is dibenzo {[f,f]-4,4′7,7′-tetraphenyl]diindeno-[1,2,3-cd: 1′,2′,3′-lm]perylene (TPDBP, Q10 above).

Other red dopants useful in the present invention belong to the DCM class of dyes represented by Formula S1: 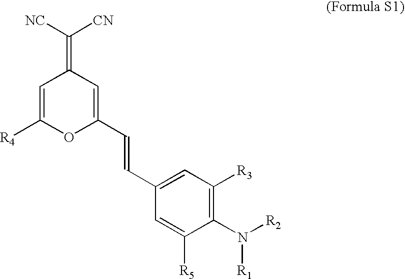
wherein R₁-R₅ represent one or more groups independently selected from: hydro, alkyl, substituted alkyl, aryl, or substituted aryl; R₁-R₅ independently include acyclic groups or are joined pairwise to form one or more fused rings; provided that R₃ and R₅ do not together form a fused ring.

In a useful and convenient embodiment that provides red luminescence, R₁-R₅ are selected independently from hydro, alkyl, and aryl. Structures of particularly useful dopants of the DCM class are shown below:

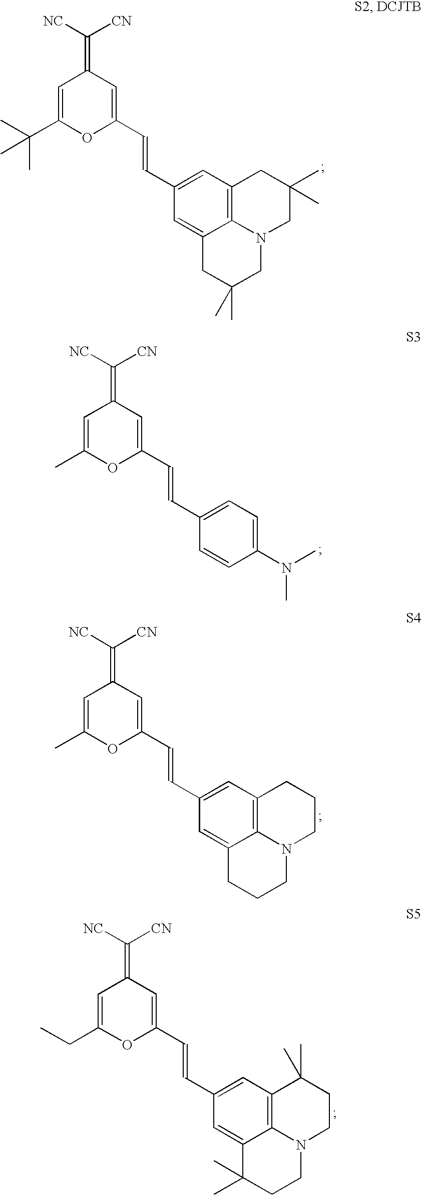

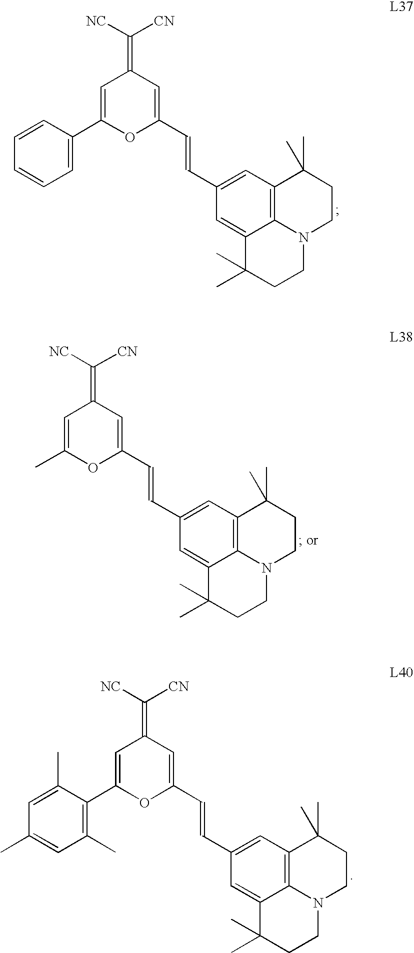

A preferred DCM dopant is DCJTB. The red dopant can also be a mixture of compounds that would also be red dopants individually.

While not always necessary, it is often useful that OLED device 10 includes an electron-transporting layer 55 disposed over light-emitting layer 50. Desired electron-transporting materials can be deposited by any suitable way such as evaporation, sputtering, chemical vapor deposition, electrochemical means, thermal transfer, or laser thermal transfer from a donor material. Preferred electron-transporting materials for use in electron-transporting layer 55 are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials.

Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials such as those listed in Handbook of Conductive Molecules and Polymers, Vols. 1-4, H. S. Nalwa, ed., John Wiley and Sons, Chichester (1997).

It will be understood that, as is common in the art, some of the layers can have more than one function. For example, layer 45 can be a hole-transporting layer that includes light-emitting dopants. Light-emitting layer 50 can have hole-transporting properties or electron-transporting properties as desired for performance of the OLED device. Hole-transporting layer 40 or electron-transporting layer 55, or both, can also have emitting properties. In such a case, fewer layers than described above can be sufficient for the desired emissive properties.

The organic EL media materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be premixed and coated from a single boat or donor sheet.

An electron-injecting layer 60 can also be present between the cathode and the electron-transporting layer. Examples of electron-injecting materials include alkaline or alkaline earth metals, alkali halide salts, such as LiF mentioned above, or alkaline or alkaline earth metal doped organic layers.

Cathode 90 is formed over the electron-transporting layer 55 or over light-emitting layer 50 if an electron-transporting layer is not used. When light emission is through the anode 30, the cathode material can be comprised of nearly any conductive material. Desirable materials have good film-forming properties to ensure good contact with the underlying organic layer, promote electron injection at low voltage, and have good stability. Useful cathode materials often contain a low work function metal (<3.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of A1 as described in U.S. Pat. No. 5,677,572. Other useful cathode materials include, but are not limited to, those disclosed in U.S. Pat. Nos. 5,059,861; 5,059,862; and 6,140,763.

When light emission is viewed through cathode 90, it must be transparent or nearly transparent. For such applications, metals must be thin or one must use transparent conductive oxides, or a combination of these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Cathode 90 is spaced, by which it is meant it is vertically spaced apart from anode 30. Cathode 90 can be part of an active matrix device and, in that case, is a single electrode for the entire display. Alternatively, cathode 90 can be part of a passive matrix device, in which each cathode 90 can activate a column of pixels, and cathodes 90 are arranged orthogonal to anodes 30.

Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

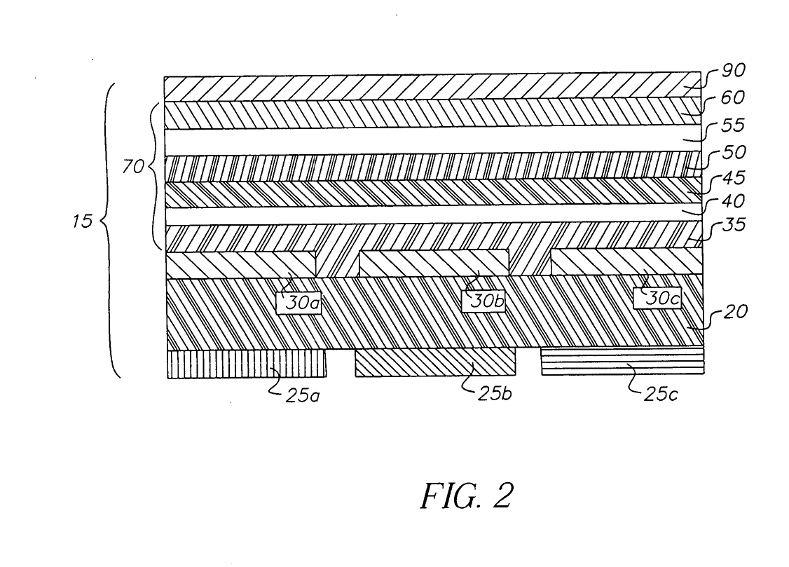

Turning now to FIG. 2, there is shown a cross-sectional view of an OLED device 15 according to another embodiment of this invention. This embodiment is similar to the previous embodiment, except that the color filter is disposed over substrate 20, and the subpixels of a full color pixel with multicolor filters are shown. The color filter array includes at least three separate filters, e.g. red color filter 25a, green color filter 25b, and blue color filter 25c, each of which forms part of a red, green, and blue subpixel respectively. Each subpixel has its own anode 30a, 30b, and 30c, respectively, which are capable of independently causing emission of the individual subpixel.

There are numerous configurations of the organic EL media layers wherein the present invention can be successfully practiced. Examples of organic EL media layers that produce white light are described, for example, in EP 1 187 235; U.S. Patent Application Publication 2002/0025419 A1; EP 1 182 244; U.S. Pat. Nos. 5,683,823; 5,503,910; 5,405,709; and 5,283,182. As shown in EP 1 187 235A2, a white light-emitting organic EL element with a substantially continuous spectrum in the visible region of the spectrum can be achieved by providing at least two different dopants for collectively emitting white light, e.g. by the inclusion of the following layers:
a hole-injecting layer 35 disposed over the anode;
a hole-transporting layer 40 that is disposed over the hole-injecting layer 35 and is doped with a light-emitting yellow dopant for emitting light in the yellow region of the spectrum;
a blue light-emitting layer 50 including a host material and a light-emitting blue dopant disposed over the hole-transporting layer 40; and
an electron-transporting layer 55.

Because such an emitter produces a wide range of wavelengths, it can also be known as a broadband emitter and the resulting emitted light known as broadband light.

For comparison purposes, a prior art white light-emitting OLED device can be prepared as described above comprising a fluorocarbon polymer (CFₓ) as the electron-injecting material, 4,4′-bis[N-(1-naphthyl)-N-phenylamino]biphenyl (NPB) as the hole-transporting material, rubrene as the light-emitting yellow dopant, 2-tert-butyl-9,10-bis(2-naphthyl)anthracene (TBADN) as the host material for the light-emitting layer, BDTAPVB (Formula L47, above) as the light-emitting blue dopant, and tris(8-quinolinolato)aluminum (III) (ALQ) as the electron-transporting material. This prior art white emitter shall be referred to as White1.

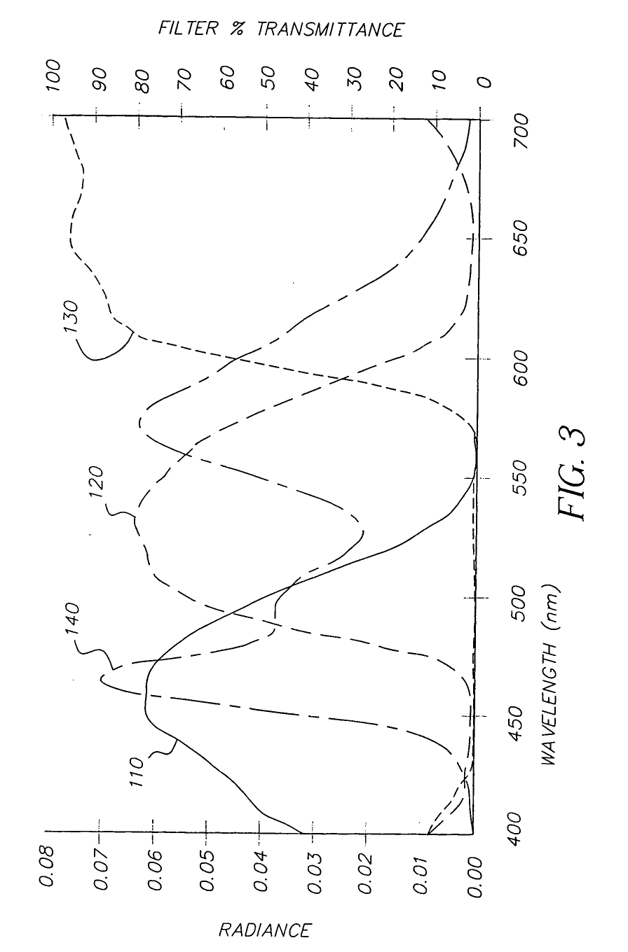

Turning now to FIG. 3, there is shown a graphical representation of the emission spectrum 140 of the White1 OLED device in comparison to commonly used color filters. Examples of such color filters include red, green, and blue TV color filters, which are commercially available. It is useful to define the color filter's bandpass spectrum, which includes the wavelengths of the visible spectrum wherein the color filter has a transmittance of 70% or greater. The bandpass spectrum of the red color filter 25a is seen to be from 605 nm to 700 nm such that it passes red light, that of the green color filter 25b to be from 495 nm to 555 nm such that it passes green light, and that of the blue color filter 25c to be from 435 nm to 480 nm such that it passes blue light. The transmission spectra of the blue, green and red color filters are shown by parts 110, 120 and 130 respectively in FIG. 3. It can be seen that White1 has significant emissions in the bandpass spectra of the blue and green color filters. In the bandpass spectrum of the red filter, however, the emission is less intense. In order to make a full color device of such a white emitter, one must increase the current through the red pixels to compensate for the reduced red emission, relative to the other colors.

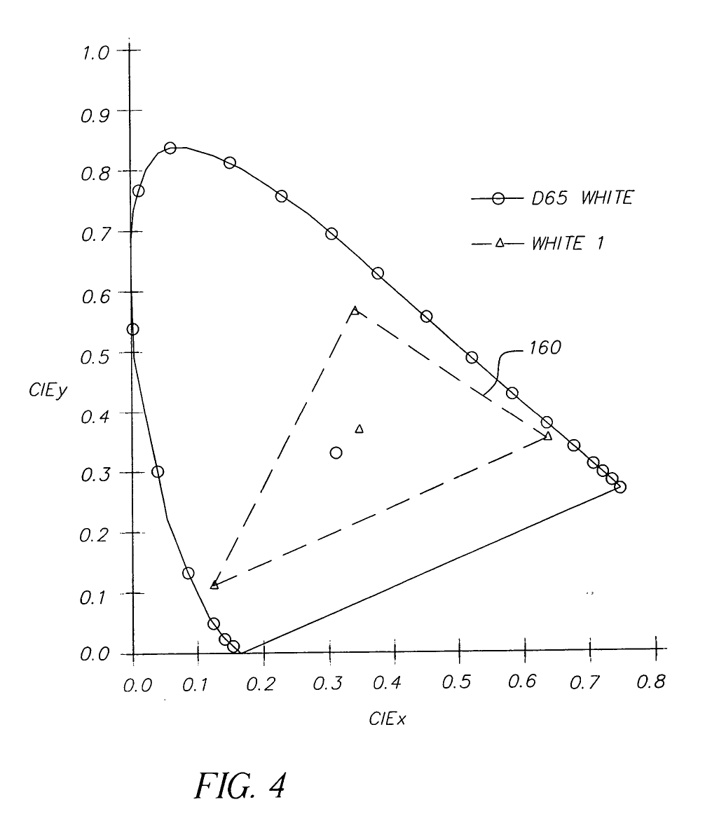

Turning now to FIG. 4, there is shown a graphical representation of the color gamut 160, shown in CIE color space, of a full color OLED device constructed from the above prior art White1 OLED device with the red, green, and blue color filters. The red pixel has CIEx,y values of 0.639 and 0.353, which is an orangish red. The green pixel has CIEx,y values of 0.343 and 0.565, which is a slightly yellowish green. The blue CIEx,y values of 0.125 and 0.115 form a good blue color.

A white light-emitting OLED device for producing white light that more effectively matches the response of multicolor filters in an OLED device can be prepared according to the present invention by inclusion of the following layers:
a hole-injecting layer 35 comprising CFₓ, disposed over the anode;
a hole-transporting layer 40 that is disposed over the hole-injecting layer 35 and including a light-emitting yellow dopant for emitting light in the yellow region of the spectrum and a light-emitting red dopant for emitting light in the red region of the spectrum;
a blue light-emitting layer 50 including a host material and a light-emitting blue dopant disposed over the hole-transporting layer 40; and
an electron-transporting layer 55.

One embodiment of the above OLED device includes a fluorocarbon polymer (CFₓ) as the electron-injecting material, 4,4′-bis[N-(1-naphthyl)-N-phenylamino]biphenyl (NPB) as the hole-transporting material, rubrene as the light-emitting yellow dopant, periflanthene as the light-emitting red dopant, 2-tert-butyl-9,10-bis(2-naphthyl)anthracene (TBADN) as the host material for the light-emitting layer, BDTAPVB (Formula L47, above) as the light-emitting blue dopant, and tris(8-quinolinolato)aluminum (III) (ALQ) as the electron-transporting material. This inventive white emitter shall be referred to as White2. The composition of the dopants is selected to change the spectrum of the white light produced by the OLED device to be compatible with the spectrum of the color filters, as will be seen.

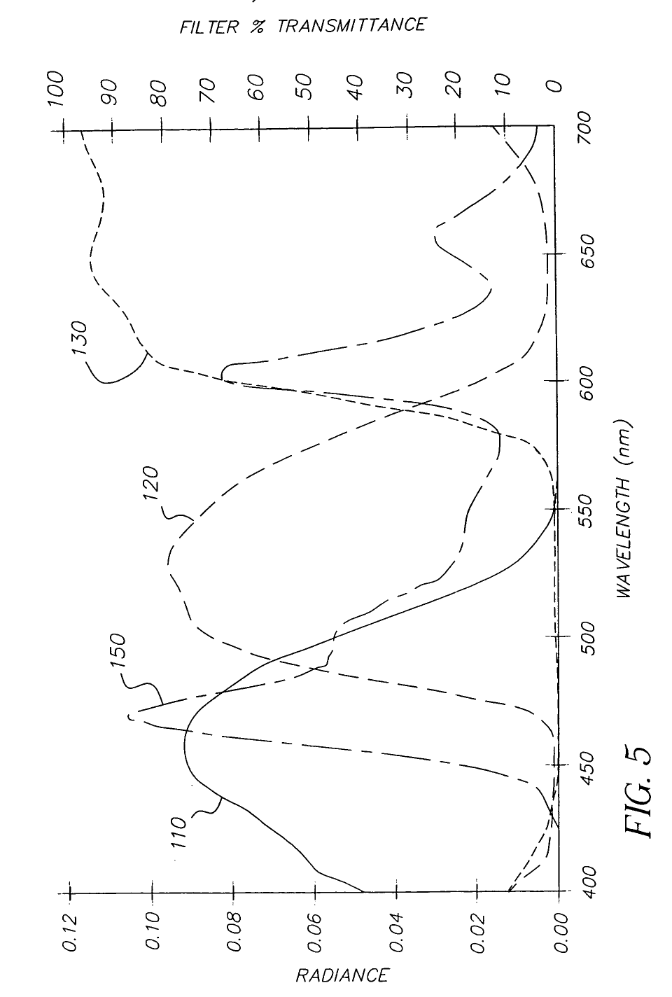

Turning now to FIG. 5, there is shown a graphical representation of the emission spectrum 150 of White2 OLED device in comparison to the commonly used color filters. It can be seen that by addition of the red dopant, White2 has significant emissions in the bandpass spectra of all three color filters, that is, red, green, and blue. White2 has peak responses in the white light spectrum corresponding to the bandpass spectra of the red and blue color filters. In comparison to White1, the spectrum of White2 aligns particularly well with the bandpass spectrum of the red color filter. A more effective match of the white light to the responses of the color filters is achieved in this embodiment by a first layer (e.g. light-emitting layer 50) having a dopant for substantially emitting light in the blue region and less light in the green region, and a second layer (e.g. hole-transporting layer 40) having one or more dopants for substantially emitting light in the red region and less light in the green region of the spectrum.

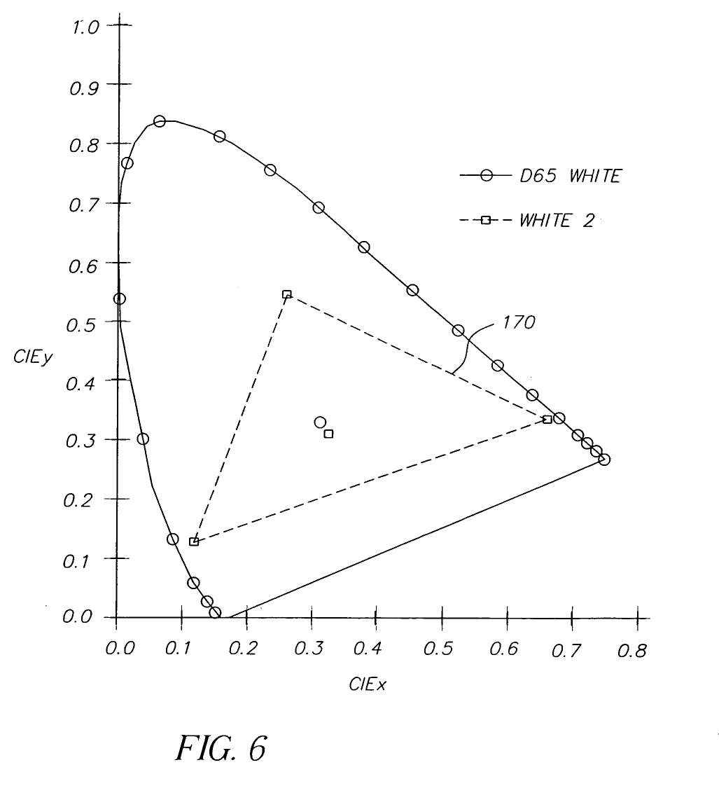

Turning now to FIG. 6, there is shown a graphical representation of the color gamut 170, shown in CIE color space, of a full color OLED device constructed from the above inventive White2 OLED device with the same red, green, and blue color filters used with the White1 OLED device. The red pixel has CIEx,y values of 0.657 and 0.337, which is a more pure red than that of the OLED device with White1. The green pixel has CIEx,y values of 0.256 and 0.555, which is a more pure green than that of the OLED device with White1. The blue CIEx,y values of 0.114 and 0.142 form a blue color. Overall, the color gamut of the full color OLED device constructed with the White2 emitter includes an improved selection of colors, particularly in the green region.

An added improvement can be obtained by further including a layer having a light-emitting green dopant that produces green light that substantially matches the color response of green color filter 25b without causing degradation of the red and blue colors. This can be achieved with a green dopant having an emission maximum within the bandpass spectrum of green color filter 25b, that is within 495 nm and 555 nm.

The invention and its advantages can be better appreciated by the following comparative examples.

### EXAMPLE 1

### Comparative Example, White1

A prior art OLED device that provides the spectral results shown in FIG. 3 and FIG. 4 was constructed in the following manner:
1. A clean glass substrate with on-chip color filters was vacuum-deposited with indium tin oxide (ITO) through a mask to form a pattern of transparent electrodes of 40 to 80 nm thickness;
2. The above-prepared ITO surface was treated with a plasma oxygen etch, followed by plasma deposition of a 0.1 nm layer of a fluorocarbon polymer (CFₓ) as described in U.S. Pat. No. 6,208,075;
3. The above-prepared substrate was further treated by vacuum-depositing a 240 nm layer of 4,4′-bis[N-(1-naphthyl)-N-phenylamino]biphenyl (NPB) as a hole-transporting layer followed by a 30 nm layer comprising a mixture of 77% NPB and 20% tBuDPN and 3% DBzR (a yellow dopant);
4. A 40 nm blue emissive layer comprising a mixture of 90% of 2-tert-butyl-9,10-bis(2-naphthyl)anthracene (TBADN) and 7.5% NPB with 2.5% 1,4-bis[2-[4-[N,N-di(p-tolyl)amino]phenyl]vinyl]benzene (BDTAPVB, a blue dopant) was vacuum-deposited onto the substrate;
5. A 10 nm electron-transporting layer of tris(8-quinolinolato)aluminum (III) (ALQ) was vacuum-deposited onto the substrate at a coating station that included a heated tantalum boat source; and
6. A 220 nm cathode layer was deposited onto the receiver element at a coating station with separate tantalum boats, one of which contained silver and one of which contained magnesium. The cathode layer was a 10:1 atomic ratio of magnesium and silver.

### EXAMPLE 2

### Inventive Example, White2

An OLED device satisfying the requirements of the invention and providing the spectral results shown in FIG. 5 and FIG. 6 was constructed in the manner described in Example 1, except that step 3 was as follows:
3. The above-prepared substrate was further treated by vacuum-depositing a 240 nm layer of 4,4′-bis[N-(1-naphthyl)-N-phenylamino]biphenyl (NPB) as a hole-transporting layer followed by a 28 nm layer comprising a mixture of 72% NPB and 27.5% rubrene (a yellow dopant) with 0.5% periflanthene (a red dopant).

The devices were tested by applying a current across the electrodes of 20 mA/cm² and measuring the luminance, color, and drive voltages with and without color filters. The following table shows the results.

| | Example 1 | Example 2 |
|---|---|---|
| | (Comparative) | (Inventive) |
| Yellow dopant | 3% DBzR + 20% | 27.5% rubrene |
| | tBuDPN | |
| Blue dopant | 2.5% | 3% BDTAPVB + |
| | BDTAPVB + | 13% NPB |
| | 7% NPB | |
| Red dopant | — | 0.5% periflanthene |
| Initial White Luminous Yield (cd/A) | 14.22 | 11.98 |
| Composite White Luminous Yield (cd/A) | 3.30 | 3.43 |
| Initial White (CIEx, y) | (0.35, 0.36) | (0.32, 0.32) |
| Power Consumption of Full color Device (W)*¹ | 1.67 | 1.60 |
| Red Luminous Yield After Filter (cd/A) | 2.28 | 2.97 |
| Red (CIEx, y) | (0.639, 0.353) | (0.657, 0.337) |
| Current Density Through Red Sub-Pixel (mA/cm²)¹ | 19.5 | 19.2 |
| Green Luminous Yield After Filter (cd/A) | 7.48 | 5.50 |
| Green (CIEx, y) | (0.343, 0.565) | (0.256, 0.555) |
| Current Density Through Green Sub-Pixel (mA/cm²)¹ | 16.4 | 19.3 |
| Blue Luminous Yield After Filter (cd/A) | 1.24 | 1.79 |
| Blue (CIEx, y) | (0.125, 0.115) | (0.114, 0.142) |
| Current Density Through Blue Sub-Pixel (mA/cm²)¹ | 23.6 | 18.9 |

*Calculation based on Device Active Area = 14.42 cm², Aperture Ratio = 0.42, Pvdd-Cv = 14 V, Polarizer Transmissivity = 0.44
¹To make a D65 White at 120 cd/m²

Initially, Example 2 does not appear to be an improvement based on overall white luminous yield, which for Example 2 is about 12 cd/A, and is lower than the 14 cd/A value of Example 1. However, the composite white luminous yield (the luminous yield through the color filter array) is higher for Example 2. Example 2 also has an initial white (CIEx,y) closer to the desired value of 0.33, 0.33 and has a lower power consumption for a full color device.

### EXAMPLE 3

### Comparative Example

A prior art OLED device was constructed in the following manner:
1. A clean glass substrate with on-chip color filters was vacuum-deposited with indium tin oxide (ITO) through a mask to form a pattern of transparent electrodes of 40 to 80 nm thickness;
2. The above-prepared ITO surface was treated with a plasma oxygen etch, followed by plasma deposition of a 0.1 nm layer of a fluorocarbon polymer (CFₓ) as described in U.S. Pat. No. 6,208,075;
3. The above-prepared substrate was further treated by vacuum-depositing a 170 nm layer of 4,4′-bis[N-(1-naphthyl)-N-phenylamino]biphenyl (NPB) as a hole-transporting layer followed by a 30 nm layer comprising NPB with 3% 6,11-diphenyl-5,12-bis(4-(6-methyl-benzothiazol-2-yl)phenyl)naphthacene (DBZR) and 20% 5,12-bis(t-butylphenyl)-naphthacene (tBuDPN) (both yellow dopants);
4. A 40 nm blue emissive layer comprising 2-tert-butyl-9,10-bis(2-naphthyl)anthracene (TBADN) with 7% NPB and 2.5% 1,4-bis[2-[4-[N,N-di(p-tolyl)amino]phenyl]vinyl]benzene (BDTAPVB, a blue dopant) was vacuum-deposited onto the substrate;
5. A 10 nm electron-transporting layer of tris(8-quinolinolato)aluminum (II) (ALQ) was vacuum-deposited onto the substrate at a coating station that included a heated tantalum boat source; and
6. A 220 nm cathode layer was deposited onto the receiver element at a coating station with separate tantalum boats, one of which contained silver and one of which contained magnesium. The cathode layer was a 10:1 atomic ratio of magnesium and silver.

### EXAMPLE 4

### Inventive Example

An OLED device satisfying the requirements of the invention and providing the spectral results shown in FIG. 5 and FIG. 6 was constructed in the manner described in Example 1, except that steps 3 and 4 were as follows:
3. The above-prepared substrate was further treated by vacuum-depositing a 280 nm layer of 4,4′-bis[N-(1-naphthyl)-N-phenylamino]biphenyl (NPB) as a hole-transporting layer followed by a 20 nm layer comprising NPB with 40% rubrene (a yellow dopant) and 0.5% periflanthene (a red dopant); and
4. A 40 nm blue emissive layer comprising 2-tert-butyl-9,10-bis(2-naphthyl)anthracene (TBADN) with 10% NPB and 3% 1,4-bis[2-[4-[N,N-di(p-tolyl)amino]phenyl]vinyl]benzene (BDTAPVB, a blue dopant) was vacuum-deposited onto the substrate.

The devices were tested by applying a current across the electrodes of 20 mA/cm² and measuring the luminance, color, and drive voltages with and without color filters. The following table shows the results.

| | Example 3 | Example 4 |
|---|---|---|
| | (Comparative) | (Inventive) |
| Yellow dopant | 3% DBzR + | 40% rubrene |
| | 20% tBuDPN | |
| Blue dopant | 7% NPB + | 10% NPB + |
| | 2.5% | 3% |
| | BDTAPVB | BDTAPVB |
| Red dopant | — | 0.5% |
| | | periflanthene |
| Green dopant | — | — |
| Initial White Luminous Yield (cd/A) | 13.33 | 10.79 |
| Drive voltage (volts) | 7.5 | 8.8 |
| Initial White (CIEx, y) | (0.355, 0.399) | (0.364, 0.321) |
| Composite white luminous yield (cd/A) | 2.82 | 3.21 |
| Power Consumption of Full | 1.96 | 1.72 |
| color Device (W)*¹ | | |
| Red Luminous Yield After Filter (cd/A) | 2.46 | 3.50 |
| Red (CIEx, y) | (0.641, 0.356) | (0.654, 0.345) |
| Green Luminous Yield | 7.06 | 4.62 |
| After Filter (cd/A) | | |
| Green (CIEx, y) | (0.301, 0.559) | (0.252, 0.519) |
| Blue Luminous Yield After | 1.40 | 1.54 |
| Filter (cd/A) | | |
| Blue (CIEx, y) | (0.111, 0.171) | (0.113, 0.149) |

¹To make a D65 White at 120 cd/m²

Relative to Example 3, Example 4 has a lower white luminous yield. However, Example 4 shows an improved composite white luminous yield (the luminous yield through the color filter array) and a lower power consumption for a full color device.

The entire contents of the patents and other publications referred to in this specification are incorporated herein by reference.

The invention has been described in detail with particular reference to certain preferred embodiments thereof, but it will be understood that variations and modifications can be effected within the spirit and scope of the invention.

### Parts List

10 OLED device
15 OLED device
20 substrate
25 color filter
25a red color filter
25b green color filter
25c blue color filter
30 anode
30a anode
30b anode
30c anode
35 hole-injecting layer
40 hole-transporting layer
45 light-emitting layer
50 light-emitting layer
55 electron-transporting layer
60 electron-injecting layer
70 organic EL element
90 cathode
110 blue color filter spectrum
120 green color filter spectrum
130 red color filter spectrum
140 White1 emission spectrum
150 White2 emission spectrum
160 White1 gamut
170 White2 gamut

1. An OLED device for producing white light which more effectively matches the response of multicolor filters in an OLED device, comprising:
a) an anode and a spaced cathode;
b) an organic EL element disposed between the anode and cathode having at least two different dopants for collectively emitting white light;
c) a color filter array disposed over the EL element and including at least three separate filters having bandpass spectra for passing red, green, and blue light, respectively, in response to white light to produce preselected color outputs; and
d) the composition of one or more of the dopants being selected to change the spectrum of the white light to be compatible with the spectrum of the color filters by having peak responses in the white light spectrum corresponding to the bandpass spectra of the red and blue color filters so that the white light more effectively matches the responses of the color filters.

2. The OLED device of claim 1 wherein the organic EL element includes a first layer having a dopant for substantially emitting light in the blue region and less light in the green region, and a second layer having a dopant for substantially emitting light in the red region and less light in the green region of the spectrum.

3. The OLED device of claim 1 wherein the bandpass spectrum of the red color filter is from 605 nm to 700 nm.

4. The OLED device of claim 1 wherein the bandpass spectrum of the green color filter is from 495 nm to 555 nm.

5. The OLED device of claim 1 wherein the bandpass spectrum of the blue color filter is from 435 nm to 480 nm.

6. The OLED device of claim 1 wherein the organic EL element includes:
i) a hole-transporting layer disposed over the anode;
ii) a blue light-emitting layer including a host material and a light-emitting blue dopant disposed over the hole-transporting layer;
iii) an electron-transporting layer disposed over the blue light-emitting layer; and
iv) the hole-transporting layer including a light-emitting yellow dopant and a light-emitting red dopant.

7. The OLED device of claim 6 wherein the host material in the blue light-emitting layer includes an anthracene derivative having hydrocarbon or substituted-hydrocarbon substituents at the 9 and 10 positions.

8. The OLED device of claim 6 wherein the light-emitting blue dopant includes perylene or a derivative of perylene.

9. The OLED device of claim 6 wherein the light-emitting blue dopant includes a blue-emitting derivative of a distyrylbenzene or a distyrylbiphenyl.

10. The OLED device of claim 6 wherein the light-emitting blue dopant includes a compound of the structure 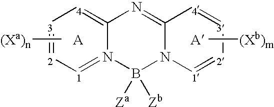
wherein:
A and A′ represent independent azine ring systems corresponding to 6-membered aromatic ring systems containing at least one nitrogen;
(X^{a})ₙ and (X^{b})ₘ represent one or more independently selected substituents and include acyclic substituents or are joined to form a ring fused to A or A′;
m and n are independently 0 to 4;
Z^{a} and Z^{b} are independently selected substituents;
1, 2, 3, 4, 1′, 2′, 3′, and 4′ are independently selected as either carbon or nitrogen atoms; and
wherein X^{a}, X^{b}, Z^{a}, and Z^{b}, 1, 2, 3, 4, 1′, 2′, 3′, and 4′ are selected to provide blue luminescence.

11. The OLED device of claim 6 wherein the light-emitting blue dopant includes a compound of the structure:

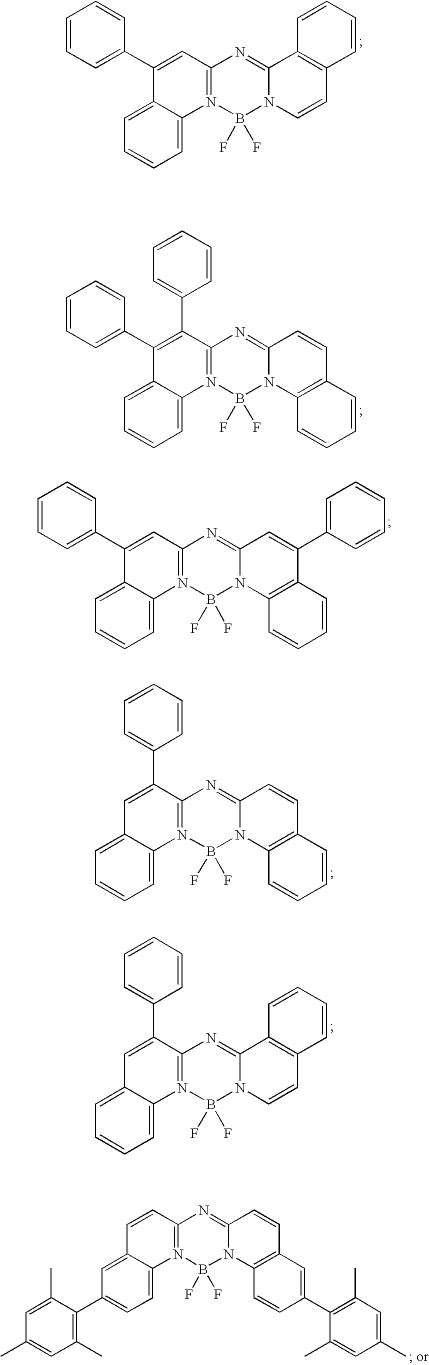

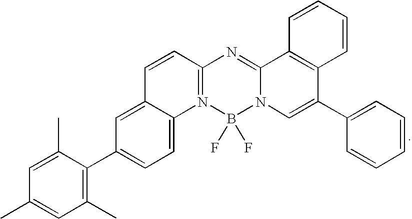

12. The OLED device of claim 6 wherein the light-emitting blue dopant includes a compound of the structure: 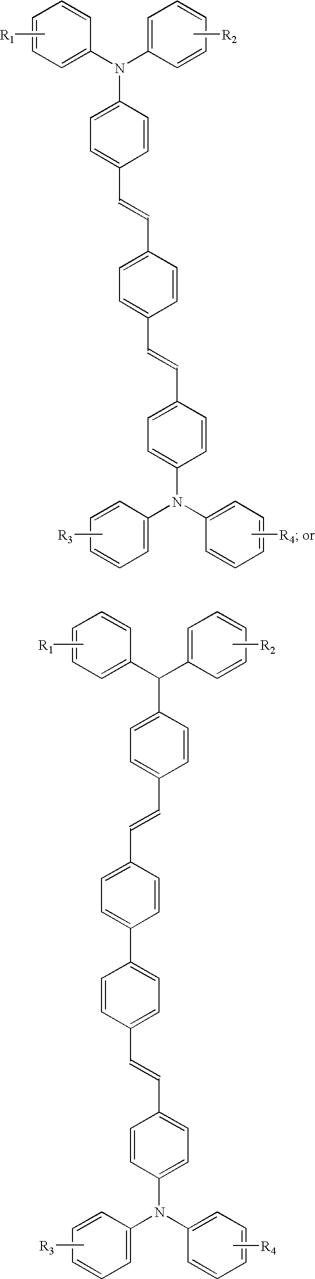
wherein R₁-R₄ can be the same or different, and individually represent one or more substituents such as alkyl, aryl, fused aryl, halo, or cyano.

13. The OLED device of claim 6 wherein the light-emitting yellow dopant includes a compound of the following structure: 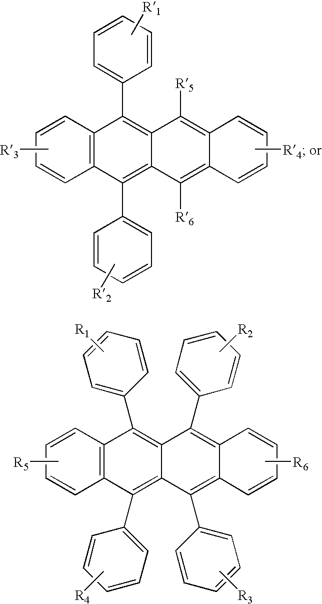
wherein R₁-R₆ represent one or more substituents on each ring and where each substituent is individually selected from one of the following:
Category 1: hydrogen, or alkyl of from 1 to 24 carbon atoms;
Category 2: aryl or substituted aryl of from 5 to 20 carbon atoms;
Category 3: hydrocarbon containing 4 to 24 carbon atoms, completing a fused aromatic ring or ring system;
Category 4: heteroaryl or substituted heteroaryl of from 5 to 24 carbon atoms such as thiazolyl, furyl, thienyl, pyridyl, quinolinyl or other heterocyclic systems, which are bonded via a single bond, or complete a fused heteroaromatic ring system;
Category 5: alkoxyamino, alkylamino, or arylamino of from 1 to 24 carbon atoms; or
Category 6: fluoro, chloro, bromo or cyano.

14. The OLED device of claim 6 wherein the light-emitting red dopant includes a diindenoperylene compound of the following structure: 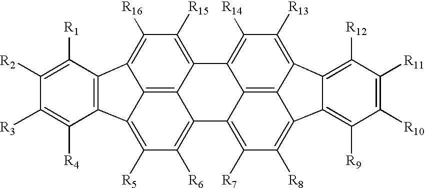
wherein:
R₁-R₁₆ are independently selected as hydro or substituents that provide red luminescence.

15. The OLED device of claim 6 wherein the light-emitting red dopant includes:

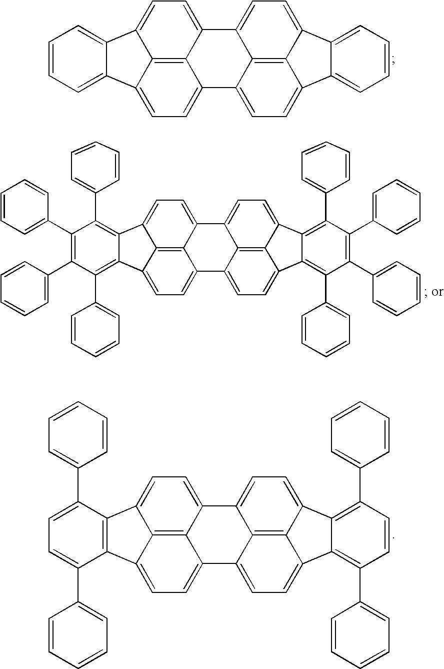

16. The OLED device of claim 6 further including a layer having a light-emitting green dopant which produces green light that substantially matches the color response of the green color filter without causing degradation of the red and blue colors.
